(19) United States
(12) Patent Application Publication
(10) Pub. No.: US 2017/0084833 A1
(43) Pub. Date: Mar. 23, 2017

(54) EMBEDDED PHASE CHANGE MEMORY DEVICES AND RELATED METHODS

(71) Applicant: STMICROELECTRONICS S.R.L., Agrate Brianza (IT)

(72) Inventors: BARBARA ZANDERIGHI, MILANO (IT); CAMILLO BRESOLIN, VIMERCATE (IT); VALERIO SPREAFICO, BERGAMO (IT)

(21) Appl. No.: 15/365,016

(22) Filed: Nov. 30, 2016

Related U.S. Application Data
(62) Division of application No. 14/574,778, filed on Dec. 18, 2014.

(51) Int. Cl. H01L 45/00; H01L 27/24

(52) U.S. Cl. CPC H01L 45/06; H01L 45/1233; H01L 45/126; H01L 45/144; H01L 45/1625; H01L 27/2463

(57) ABSTRACT

A method for making an integrated circuit (IC) including embedded phase change memory (PCM) may include forming an array of heating elements above a substrate including processing circuitry thereon, and forming a respective PCM chalcogenide glass layer above each heating element. This may be done by forming a tellurium-rich, germanium-antimony-tellurium (GST) layer above the heating element, and forming a germanium-rich GST layer above the tellurium-rich GST layer. In another embodiment, the method may include forming the PCM glass layers to have a nitrogen concentration doping profile that increase in a direction upward from the heating element.

### TECHNICAL FIELD

The present invention relates to the field of electronic devices and, more particularly, to memory devices and related methods.

### BACKGROUND

Phase-change memories (PCMs) are a type of non-volatile random-access memory which utilize the unique characteristics of chalcogenide glass. In typical PCM configurations, heat produced by passing an electric current through a heating element (e.g., a titanium nitride element) is used to change the state of the chalcogenide glass material, making it either amorphous or switching it to a crystalline state.

Embedded PCMs may require much higher retention performance with respect to traditional PCMs. For this reason a Germanium-rich GST alloys have been studied and used for certain embedded PCM configurations. However, such alloys may have relatively poor cycling performance. Thus, further improvements may be desirable for embedded PCM implementations.

### SUMMARY

A method for making an integrated circuit (IC) including embedded phase change memory (PCM) may include forming an array of heating elements above a substrate including processing circuitry thereon, and forming a respective PCM chalcogenide glass layer above each heating element. This may be done by forming a tellurium-rich, germanium-antimony-tellurium (GST) layer above the heating element, and forming a germanium-rich GST layer above the tellurium-rich GST layer.

More particularly, forming the germanium-rich GST layer may include forming the germanium-rich GST layer to have a nitrogen doping concentration that is greater than a nitrogen doping concentration of the tellurium-rich GST layer. A nitrogen doping concentration profile of the germanium-rich GST layer may increase in a direction upward from the tellurium-rich GST layer, for example. The method may further include forming a respective cap layer above each chalcogenide glass layer, such as a titanium nitride cap layer, for example. The method may also include forming a respective contact layer above each chalcogenide glass layer. By way of example, the tellurium-rich GST layer may have a thickness in a range of 30 to 100 Angstroms. Moreover, forming the chalcogenide glass layers may include depositing the chalcogenide glass layers via physical vapor deposition, for example.

A related integrated circuit may include a substrate including processing circuitry thereon, and embedded PCM coupled to the processing circuitry and including an array of heating elements above the substrate, and a respective PCM chalcogenide glass layer above each heating element. Each chalcogenide glass layer may include a tellurium-rich, GST layer above the heating element, and a germanium-rich GST layer above the tellurium-rich GST layer.

Another related method for making an integrated circuit including embedded PCM may include forming an array of heating elements above a substrate including processing circuitry thereon. The method may also include forming a respective PCM chalcogenide glass layer above each heating element to have a nitrogen doping concentration that increases in a direction upward from the heating element.

### BRIEF DESCRIPTION OF THE DRAWINGS

FIG. 1 is a top view of an example integrated circuit (IC) including a phase change memory (PCM) in accordance with an example embodiment.

FIG. 2 is a cross-sectional diagram of an example PCM cell which may be used in the embedded PCM memory array of the IC of FIG. 1.

FIG. 3 is a flow diagram illustrating a method of making the IC of FIG. 1 including memory cells as shown in FIG. 2.

FIG. 4 is a cross-sectional diagram of another example PCM cell which may be used in the embedded PCM memory array of the IC of FIG. 1.

FIG. 5 is a flow diagram illustrating a method of making the IC of FIG. 1 including memory cells as shown in FIG. 4.

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similarly elements in different embodiments.

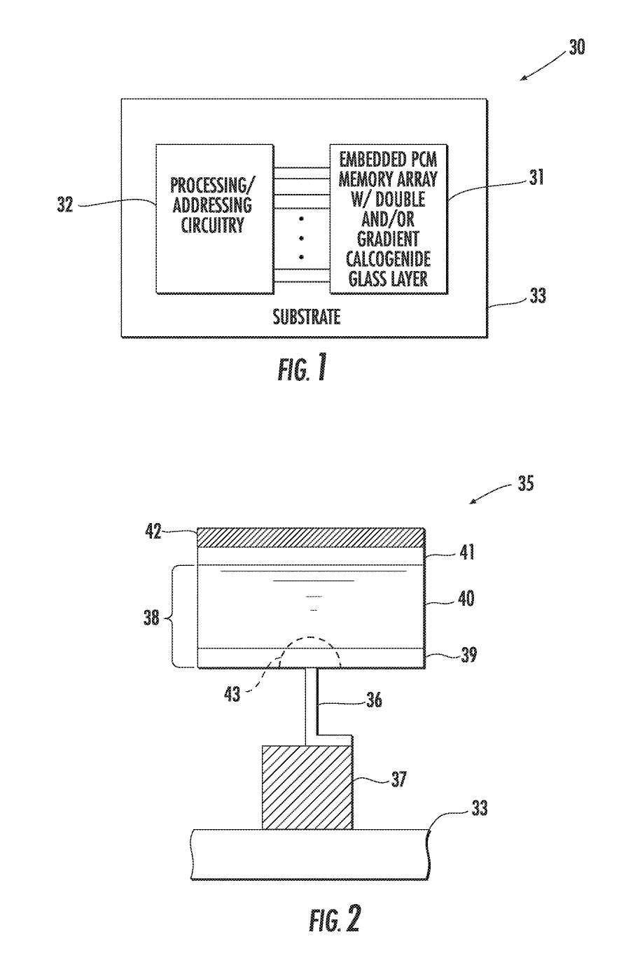

Generally speaking, the example embodiments set forth herein relate to phase change memories (PCMs), which are also referred to an ovonic cell memories or PRAMs. Referring initially to FIGS. 1-3 an integrated circuit (IC) 30 and a method for making the IC is first described. The IC 30 illustratively includes one or more embedded PCM arrays 31, and processing addressing circuitry 32, as will be appreciated by those skilled in the art. The processing/addressing circuit 32 and the embedded PCM array are formed on a substrate 33, which may be a semiconductor (e.g., silicon) substrate, for example, although other suitable substrate materials may also be used in different embodiments.

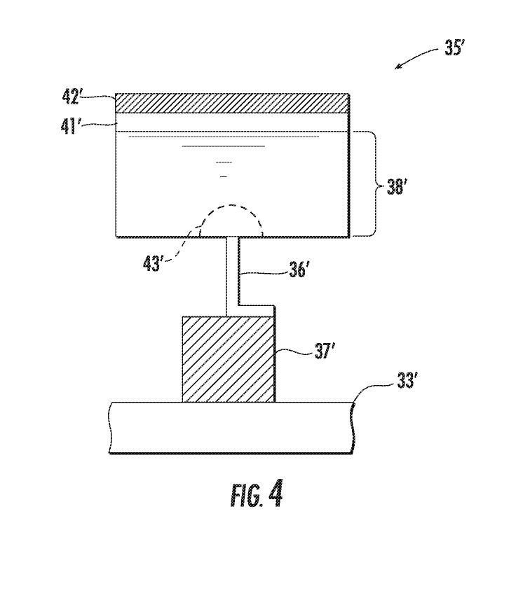

Beginning at Block 51 of the flow diagram 50 of FIG. 3, PCM cells 35 in the array 31 may be fabricated by forming an array of heating elements 36 above the substrate 33, at Block 52. More particularly, each heating element 36 may be connected to a metal contact 37 carried by the substrate 33, such as a tungsten contact, although other suitable materials may also be used in different embodiments. By way of example, the heating elements 36 may include TiSiN, but again other suitable heating element materials may be used in different embodiments.

In the present example, a two-part chalcogenide glass layer 38 is formed above the heating element 36 as the PCM material of the memory cell 35, which is a germanium-antimony-tellurium (GST) chalcogenide glass layer. However, as opposed to a single uniform GST layer, a first tellurium-rich GST layer 39 is formed above the heating element 36, and a germanium-rich GST layer 40 (i.e., a θ alloy layer) is formed above the tellurium-rich GST layer, at Blocks 53-54. The method may further illustratively include forming a respective cap layer 41 above each θ alloy layer 40 (Block 55), such as a titanium nitride cap layer, for example. The method may also include forming a respective contact layer 42 above the chalcogenide glass layer 38 and cap layer 41, at Block 56, which illustratively concludes the method of FIG. 3 (Block 57) By way of example, the contact layer 42 may also be a metal layer, such as a tungsten layer.

Adding the relatively thin “under” layer of tellurium-rich GST 39 beneath the θ alloy layer 40 has been found to help the PCM cell 35 meet not only thermal stability requirements, but also cycling requirements for a high density cell array, e.g., 50 nm cell dimensions and smaller. More particularly, the relatively thin under-layer 39 helps to modulate interface properties at a switching region 43 separately from the bulk properties of the e alloy layer 40, as will be appreciated by those skilled in the art. By way of example, the tellurium-rich GST layer 39 may have a thickness in a range of 30 to 100 Angstroms, and more particularly about 50 Angstroms, although different thicknesses may be used in different embodiments.

The PCM chalcogenide glass layers 39, 40 may be deposited via physical vapor deposition techniques (from single or multiple sources), although other suitable techniques such as chemical vapor deposition (CVD) or atomic layer deposition (ALD) may also be used in some embodiments. In one example embodiment, the tellurium and germanium-rich chalcogenide glass layers 39, 40 may be separately formed in two steps, in a single or separate processing chambers. However, in some configurations, instead of two separate layer deposition steps, the chalcogenide glass layer 38 may be formed in a single step in which the composition is varied progressively, without a sharp separation (e.g., by PVD co-sputtering). However, distinct profiles may still be present in the tellurium-rich GST layer 39 and the germanium-rich layer 40, despite being formed in a single process flow, as will be appreciated by those skilled in the art.

Using the above-described techniques, development lots were created that confirmed a double layer GST deposition as described with reference to FIG. 3 can match both retention and cycling performance expectations. The proposed cell 35, when implemented in the IC 30, displays an almost 10× factor improvement on cycling endurance with respect previous processes (i.e., one uniform alloy layer only) without affecting other device performance characteristics (e.g., yield, retention at RT or after bake). Thus, the above-described configuration may be well suited for incorporation in embedded PCM (ePCM) for 50 nm, for smaller dimensions as well.

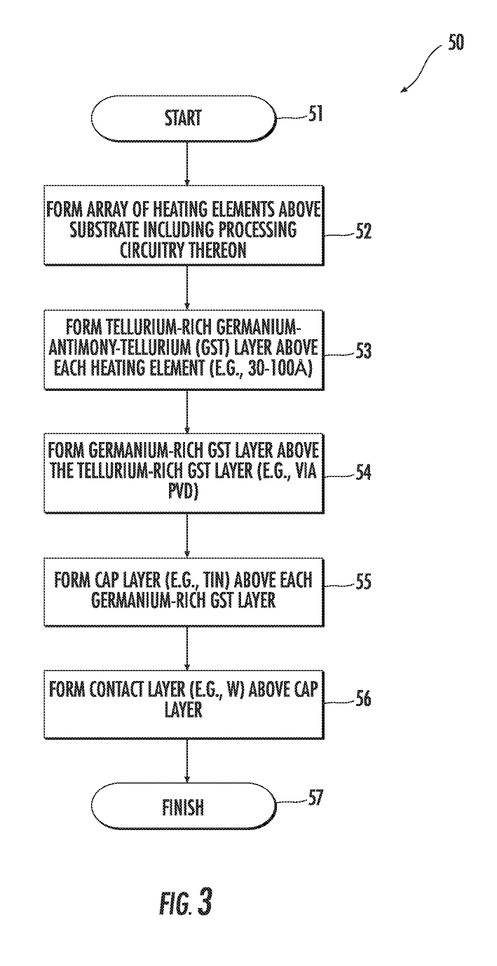

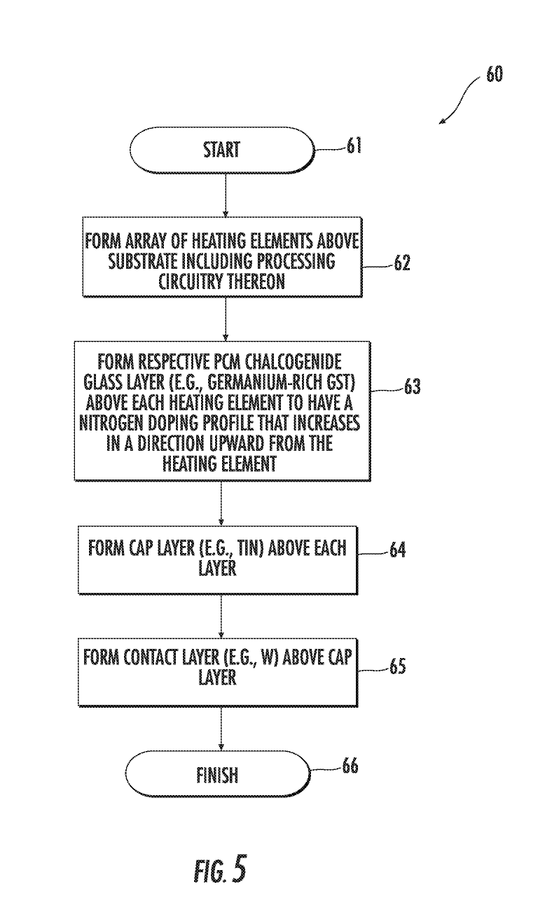

In accordance with another example approach now described with reference to FIG. 4 and the flow diagram 60 of FIG. 5, another related method for making the IC 30 and embedded PCM memory array 31 is now described. As similarly described above, beginning at Block 61, an array of heating elements 36′ may be formed above a substrate 33′ on respective metal contacts 37′. The method may also include forming a respective PCM chalcogenide glass layer 38′ above each heating element 36′, but in this example chalcogenide glass layer has a nitrogen doping concentration profile that increases in a direction upward from the heating element, as indicated by the gradient shading FIG. 4. In other words, similar to the GST glass layer 38 in FIG. 2, the GST glass layer 38′ of FIG. 4 will also have distinct material profiles in the lower portion of the GST glass where the switch 43′ is located, and in the upper portion of the GST glass layer adjacent the cap layer 41′. Yet, here the difference will be a lower-to-higher nitrogen concentration, as opposed to a higher-to-lower tellurium concentration (or, alternatively, a lower-to-higher germanium concentration).

More particularly, the relatively higher concentration of nitrogen in the upper portion of the layer 38′ advantageously helps improve set drift in the memory cell 35′. Yet, having a gradient doping concentration profile with little or no nitrogen in the lower portion of the layer 38′ may advantageously also allow for the desired nitrogen doping at the switching region 43′ to meet thermal cycling requirements. The method may further include forming the cap layer 41′ and the metal contact layer 42′, as similarly described above (Block 64-65), which illustratively concludes the method of FIG. 5 (Block 66).

Set drift may be an important issue which affects PCMs cells retention performance, i.e. the ability to retain the binary information for a specified duration under a thermal stress. More particularly, cells in the low resistance set state from germanium rich chalcogenide alloys may show the tendency, at room temperature, to increase their resistance leading to a single bit reading error. Set drift has a direct correlation with alloy composition and film contaminants. In this respect, in the above-described approach the chalcogenide alloy may be deposited while introducing a dopant, i.e., nitrogen with a gradient concentration which increases from the bottom to the top of the layer 38′. In this way the dopant distribution, throughout the chalcogenide layer 38′, allows the desired doping concentration in the cell switch region 43′ near the heater element 36′. In the remaining part of the layer 38′ the dopant will be set up or raised to the concentration that allows best yield performances, as will be appreciated by those skilled in the art.

In accordance with one example approach, the chalcogenide glass may be deposited by PVD in an AMAT ENDURA cluster. A pulsed DC bias is applied to a mono source target (cathode) in a deposition chamber kept at pressure of a few mTorr with an inert gas (Ar). The pulsed electrical field applied to target sustains a plasma from which argon ions are acellerated to the chathode where the target material erosion occurs, resulting in a thin solid film deposition in direct contact to the heater element 36′. In this embodiment a second gas, i.e., the nitrogen doping source, is gradually injected into the ionized plasma allowing alloy reactive sputtering or N gas inclusion in the growing film with a gradient doping concentration, as noted above. Such an “engineered” chalcogenide glass or alloy advantageously allows the desired doping concentration to be reached in the different regions or the layer 38′ to thereby allow set-reset issue correction, while still retaining desired cell electric performances. It should also be noted that sputtering from a solid N-doped target or nitrogen implantation onto the deposited film may also be used to reach similar results, although with potentially different performances, as will be appreciated by those skilled in the art. Moreover, the gradient doping approach may more generally be used with other PVD metal layers that need to have different behaviors in specific regions, as will also be understood by those skilled in the art.

It should also be noted that the stepped or gradient doping concentration (e.g., nitrogen concentration profile) used in the layer 38′ may also be used in the double-layer configuration set forth in FIG. 3. More particularly, the germanium-rich GST layer 40 may similarly have a nitrogen doping concentration profile that is greater than a nitrogen doping concentration profile of the tellurium-rich GST layer 39. For example, this may be done by not introducing any nitrogen in the processing flow during formation of the tellurium-rich GST layer 39, and then beginning a nitrogen flow (e.g., constant or changing) during the deposition of the germanium-rich GST layer 40. Here again, the nitrogen doping concentration profile of the germanium-rich GST layer 40 may increase in a direction upward from the tellurium-rich GST layer (i.e., a gradient profile), for example, as similarly described above for the layer 38′ in FIG. 4.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1-15. (canceled)

16. A method for making an integrated circuit (IC) including embedded phase change memory (PCM), the method comprising:
forming an array of heating elements above a substrate including processing circuitry thereon; and
forming a respective PCM chalcogenide glass layer above each heating element to have a nitrogen doping concentration that increases in a direction upward from the heating element.

17. The method of claim 16 further comprising forming a respective cap layer above each PCM chalcogenide glass layer.

18. The method of claim 17 wherein the cap layer comprises titanium nitride.

19. The method of claim 16 further comprising forming a respective contact layer above each PCM chalcogenide glass layer.

20. The method of claim 16 wherein forming the PCM chalcogenide glass layers comprises depositing the PCM chalcogenide glass layers via physical vapor deposition.

21. An integrated circuit (IC) comprising:
a substrate including processing circuitry thereon; and
embedded phase change memory (PCM) coupled to said processing circuitry and comprising
an array of heating elements above said substrate, and
a respective PCM chalcogenide glass layer above each heating element with a nitrogen doping concentration profile that increases in a direction upward from the heating element.

22. The integrated circuit of claim 21 further comprising a respective cap layer above each PCM chalcogenide glass layer.

23. The integrated circuit of claim 22 wherein the cap layer comprises titanium nitride.

24. The integrated circuit of claim 21 further comprising a respective contact layer above each PCM chalcogenide glass layer.

25. (canceled)

26. The method of claim 16 wherein forming the PCM chalcogenide glass layers comprises depositing the PCM chalcogenide glass layers while introducing the nitrogen.

27. The method of claim 16 wherein forming the PCM chalcogenide glass layers comprises generating a plasma above a target, and accelerating argon ions to the target to cause target material erosion.

28. The method of claim 16 wherein forming the PCM chalcogenide glass layers comprises sputtering from a solid nitrogen doped target.

29. The method of claim 16 wherein forming the PCM chalcogenide glass layers comprises nitrogen implantation into deposited PCM chalcogenide glass layers.

30. The method of claim 16 wherein forming the PCM chalcogenide glass layers comprises sputtering from a solid nitrogen doped target.

31. The method of claim 16 wherein forming the PCM chalcogenide glass layers comprises forming germanium-antimony-tellurium (GST) layers.

32. The integrated circuit of claim 21 wherein the PCM chalcogenide glass layers comprise germanium-antimony-tellurium (GST) layers.

33. A method for making an integrated circuit (IC) including embedded phase change memory (PCM), the method comprising:
forming an array of heating elements above a substrate including processing circuitry thereon;
forming a respective PCM chalcogenide glass layer above each heating element to have a nitrogen doping concentration that increases in a direction upward from the heating element, the PCM chalcogenide glass layers comprising germanium-antimony-tellurium (GST) layers; and
forming a respective cap layer above each PCM chalcogenide glass layer.

34. The method of claim 33 wherein each cap layer comprises titanium nitride.

35. The method of claim 33 further comprising forming a respective contact layer above each cap layer.

36. The method of claim 33 wherein forming the PCM chalcogenide glass layers comprises depositing the PCM chalcogenide glass layers via physical vapor deposition.
